(19) United States
(12) Patent Application Publication
(10) Pub. No.: US 2026/0214965 A1
(43) Pub. Date: Jul. 23, 2026

(54) CFET STRUCTURE FORMED BY A LOW TEMPERATURE PROCESS

(71) Applicant: TAIWAN SEMICONDUCTOR MANUFACTURING COMPANY, LTD., Hsinchu (TW)

(72) Inventors: I Fan HU, Hsinchu (TW); Cheng-Ming LIN, Kaohsiung (TW); Kai-Chieh YANG, New Taipei (TW); Szu-Hua CHEN, Tainan (TW); Wei-Yen WOON, Taoyuan (TW); Szuya LIAO, Hsinchu (TW)

(21) Appl. No.: 19/033,681

(22) Filed: Jan. 22, 2025

(51) Int. Cl. H10D 84/01; H10D 84/85

(52) U.S. Cl. CPC H10D 84/0181; H10D 84/851; H10D 84/856

(57) ABSTRACT

Embodiments of the present disclosure provide CFET structures and methods of forming the same. The structure includes a first transistor including a first gate structure including a first number of dielectric layers and a first conductivity type dipole dopant, and a peak concentration of the first conductivity type dipole dopant is located at an interface between a first interfacial layer and a first gate dielectric layer of the first number of dielectric layers. The structure further includes a second transistor disposed over the first transistor, and the second transistor includes a second gate structure including a second number of dielectric layers and a second conductivity type dipole dopant opposite the first conductivity type, the second number is different from the first number, and a peak concentration of the second conductivity type dipole dopant is located in a dipole layer of the second number of dielectric layers.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, and 6 are perspective views of various stages of manufacturing a semiconductor device structure, in accordance with some embodiments.

FIGS. 7A, 8A, 9A, 10A, 11A, 12A, and 13A are cross-sectional side views of various stages of manufacturing the semiconductor device structure taken along line A-A of FIG. 6, in accordance with some embodiments.

FIGS. 7B, 8B, 9B, 10B, 11B, 12B, and 13B are cross-sectional side views of various stages of manufacturing the semiconductor device structure taken along line B-B of FIG. 6, in accordance with some embodiments.

FIGS. 7C, 8C, 9C, 10C, 11C, 12C, and 13C are cross-sectional side views of various stages of manufacturing the semiconductor device structure taken along line C-C of FIG. 6, in accordance with some embodiments.

FIGS. 14, 15, 16, 17, 18, 19, 20, 21, and 22 are cross-sectional side views of various stages of manufacturing the semiconductor device structure taken along line A-A of FIG. 6, in accordance with some embodiments.

FIG. 23 is a cross-sectional side view of a portion of a gate structure, in accordance with alternative embodiments.

### DETAILED DESCRIPTION

The present disclosure relates generally to integrated circuit (IC) devices, and more particularly, to IC devices having stacked device structures, such as a transistor stack having an n-type transistor and a p-type transistor (i.e., complementary field effect transistors (CFETs)).

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features-but not mathematically or perfectly vertical and horizontal.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, FinFETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

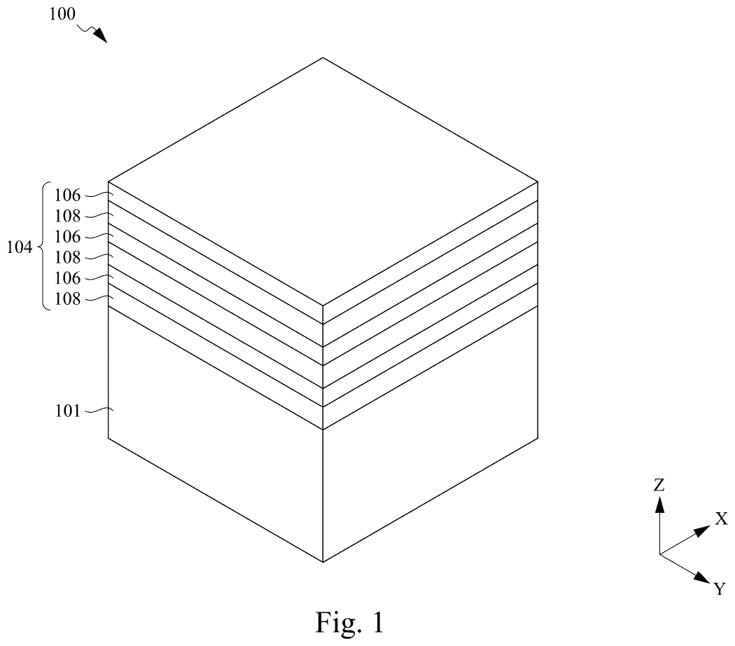

FIGS. 1-22 show exemplary processes for manufacturing a semiconductor device structure 100 according to embodiments of the present disclosure. It is understood that additional operations can be provided before, during, and after processes shown by FIGS. 1-22, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

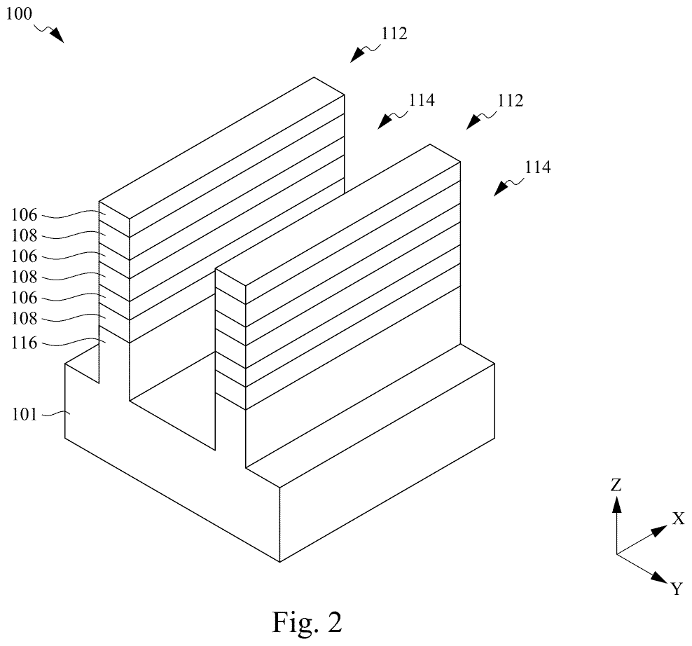

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof. In some embodiments, each fin structure 112 has a longitudinal axis along the X direction.

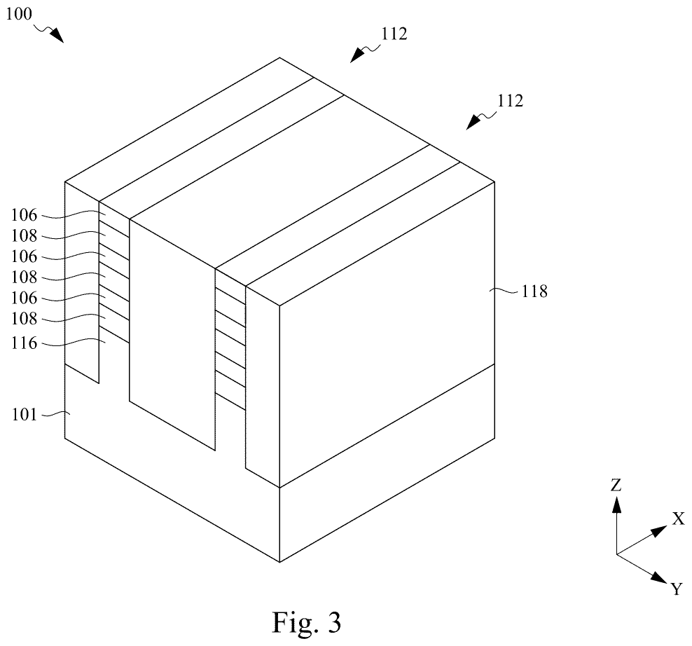

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

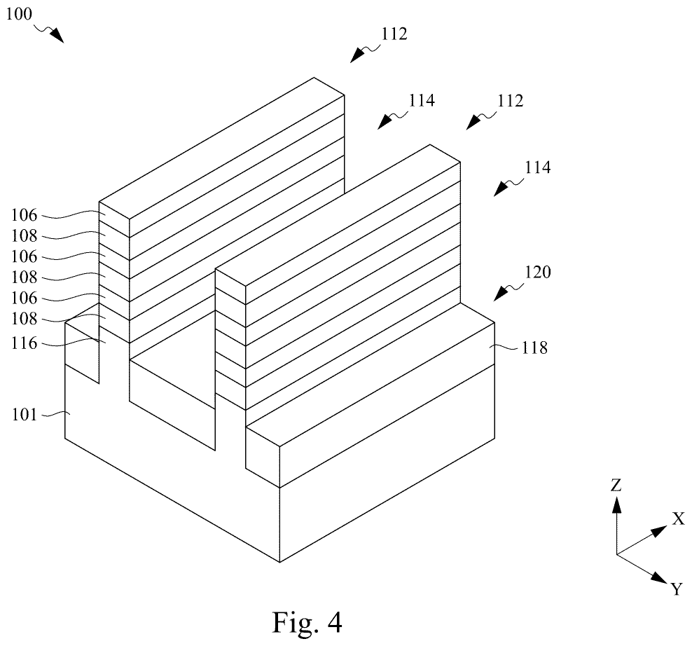

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

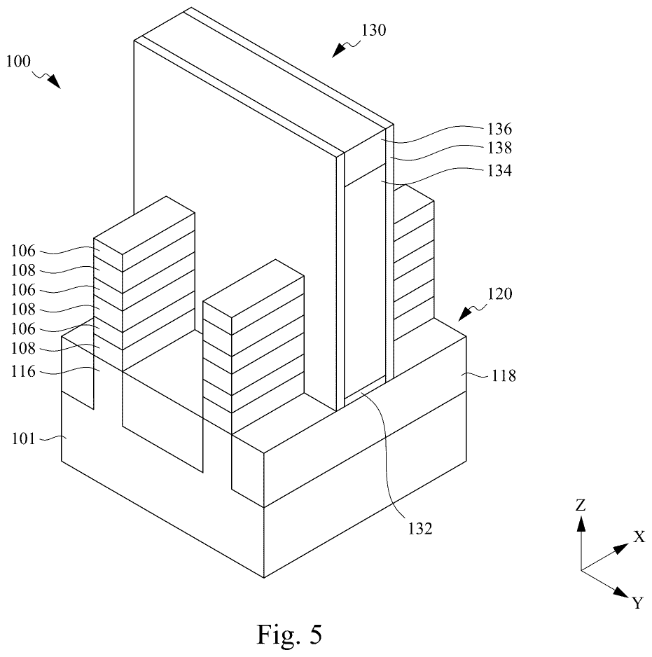

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on the sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

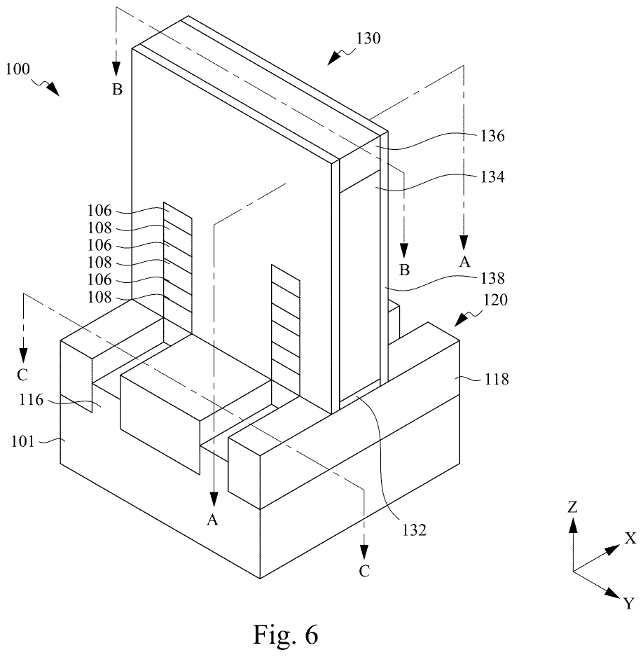

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

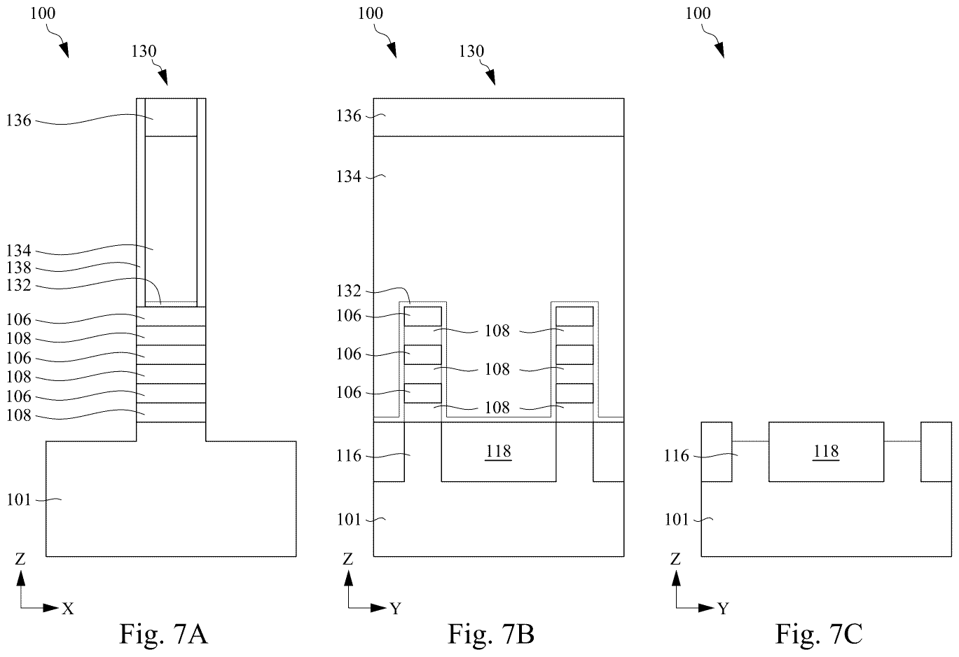

FIGS. 7A, 7B, and 7C are cross-sectional side views of the semiconductor device structure 100 taken along line A-A, line B-B, and line C-C of FIG. 6, respectively.

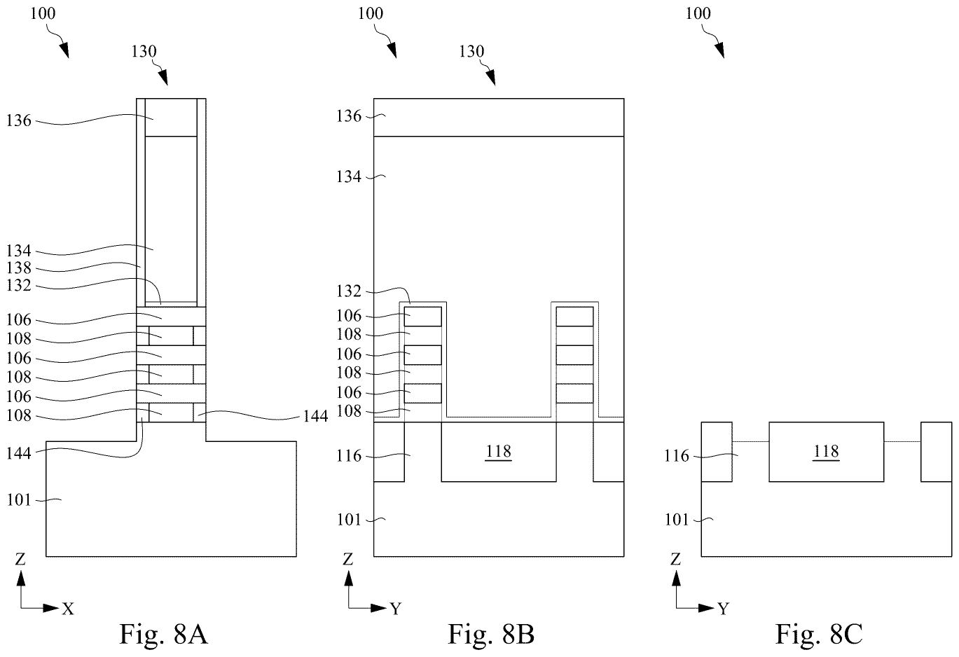

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layer 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

In some embodiments, instead of removing the edge portions of each second semiconductor layer 108, the second semiconductor layers 108 are removed and replaced with a dielectric material, such as high-density SiN or SiO. The edge portions of the dielectric material are removed, and the dielectric spacers 144 are formed to cap the dielectric material.

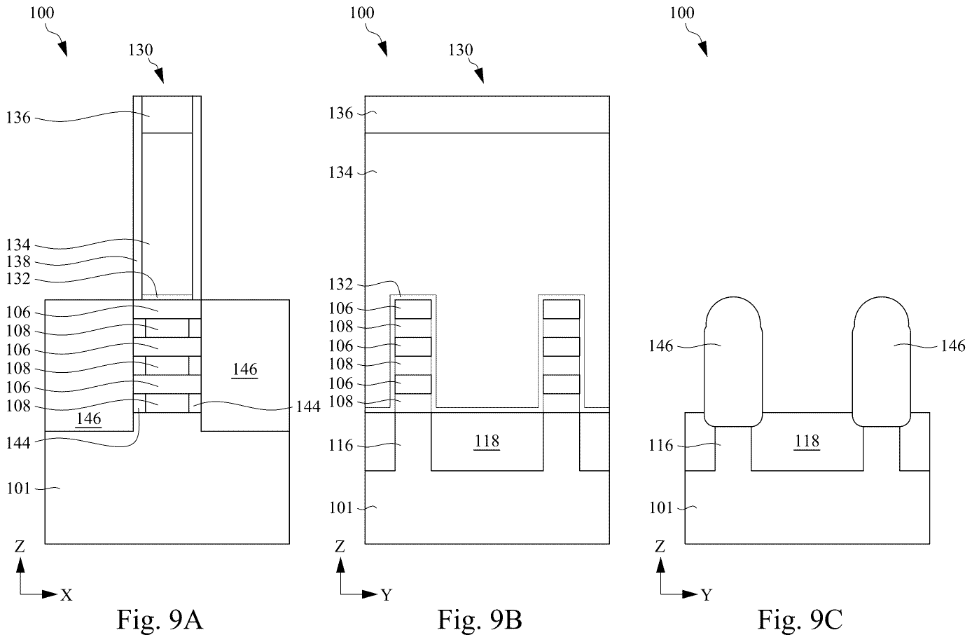

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) regions 146 are formed from the substrate portions 116. In some embodiments, the S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

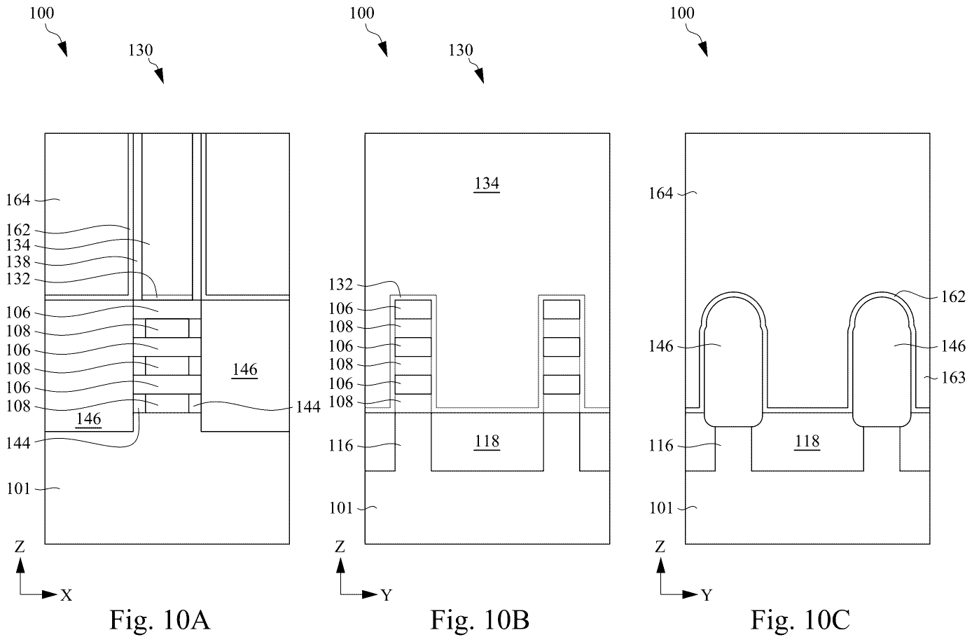

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to cure the ILD layer 164.

After the ILD layer 164 is formed, a planarization operation, such as CMP, is performed on the semiconductor device structure 100 until the sacrificial gate electrode layer 134 is exposed, as shown in FIGS. 10A and 10B.

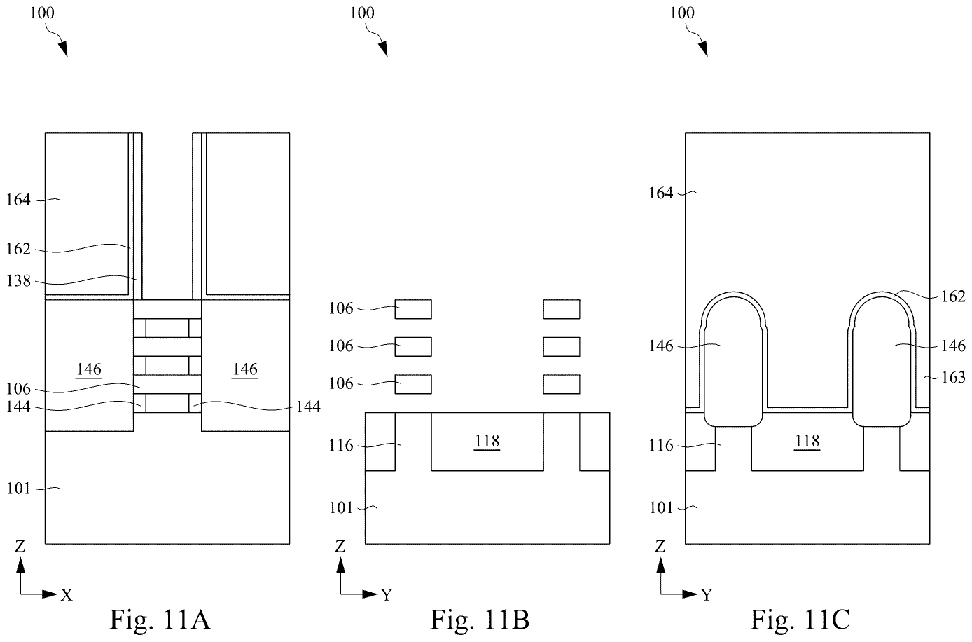

FIGS. 11A, 11B, and 11C are cross-sectional side views of one of various stages of manufacturing the semiconductor device structure 100 taken along line A-A, line B-B, and line C-C of FIG. 6, respectively, in accordance with some embodiments. As shown in FIGS. 11A and 11B, the sacrificial gate structures 130 and the second semiconductor layers 108 removed. The removal of the sacrificial gate structure 130 and the semiconductor layers 108 forms an opening between gate spacers 138 and between first semiconductor layers 106. The dielectric materials of the ILD layer 164, the gate spacers 138, and the dielectric spacers 144 are not substantially affected by the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the dielectric material 166, the dielectric layer 163, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, the dielectric material 166, the dielectric layers 163, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

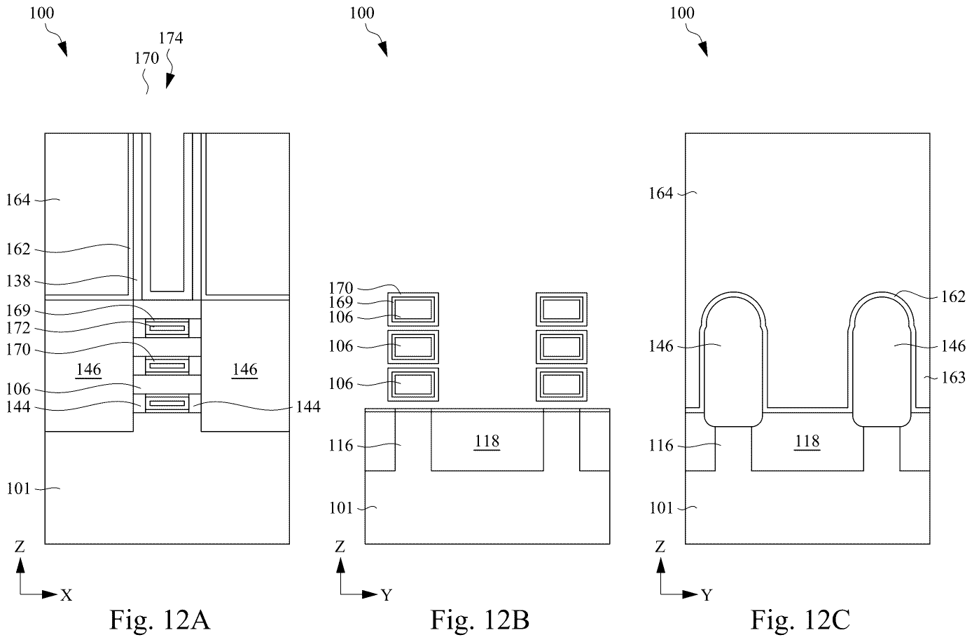

FIGS. 12A, 12B, and 12C are cross-sectional side views of one of various stages of manufacturing the semiconductor device structure 100 taken along line A-A, line B-B, and line C-C of FIG. 6, respectively, in accordance with some embodiments. As shown in FIGS. 12A and 12B, after the formation of the nanostructure channels (i.e., the exposed portions of the first semiconductor layers 106), a gate dielectric layer 170 is formed to surround the exposed portions of the first semiconductor layers 106. In some embodiments, an interfacial layer (IL) 169 is formed between the gate dielectric layer 170 and the exposed surfaces of the first semiconductor layers 106. In some embodiments, the IL 169 is formed by oxidation of the first semiconductor layer 106. The IL 169 may have a thickness ranging from about 1 nm to about 1.5 nm. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique.

Next, a dipole process is performed to modulate a threshold voltage of a transistor to be formed. In some embodiments, a dipole layer (not shown) is first deposited on the gate dielectric layer 170. The dipole layer may be formed by any suitable process, such as ALD or CVD. The dipole layer is a dielectric layer including an n-dipole dopant or a p-type dopant. In some embodiments, the n-dipole dopant or the p-dipole dopant may include a metal, such as La, Sr, Er, Mg, for n-dipole dopant or Al or Ti for p-dipole dopant. The dipole layer may include oxygen, nitrogen, carbon, or combinations thereof. In some embodiments, the dipole layer includes the n-dipole dopant. After the deposition of the dipole layer, a thermal process is performed to drive the n-dipole dopant or the p-dipole dopant into the gate dielectric layer 170. The thermal process may be any suitable process, such as annealing process, for example a rapid thermal annealing (RTA), a millisecond annealing (MSA), a microsecond annealing (pSA), a microwave annealing, a laser annealing, a spike annealing, a soak annealing, a furnace annealing, other suitable annealing process, or a combination thereof. The thermal process may have a processing temperature of 500 degrees Celsius or higher. The thermal process causes the n-dipole dopant or p-dipole dopant to diffuse into the gate dielectric layer 170. In some embodiments, the n-dipole dopant or p-dipole dopant is also diffused into the IL 169. As a result, in some embodiments, the gate dielectric layer 170 includes the n-dipole dopant or p-dipole dopant. In some embodiments, the peak n-dipole dopant concentration or peak p-dipole dopant concentration is located at an interface between the gate dielectric layer 170 and the IL 169.

After the thermal process, the dipole layer is removed. The dipole layer may be removed by any suitable process, such as a dry etch process, a wet etch process, or a combination thereof. The process to remove the dipole layer may be a selective process that does not substantially affect the gate dielectric layer 170 and the ILD layer 164.

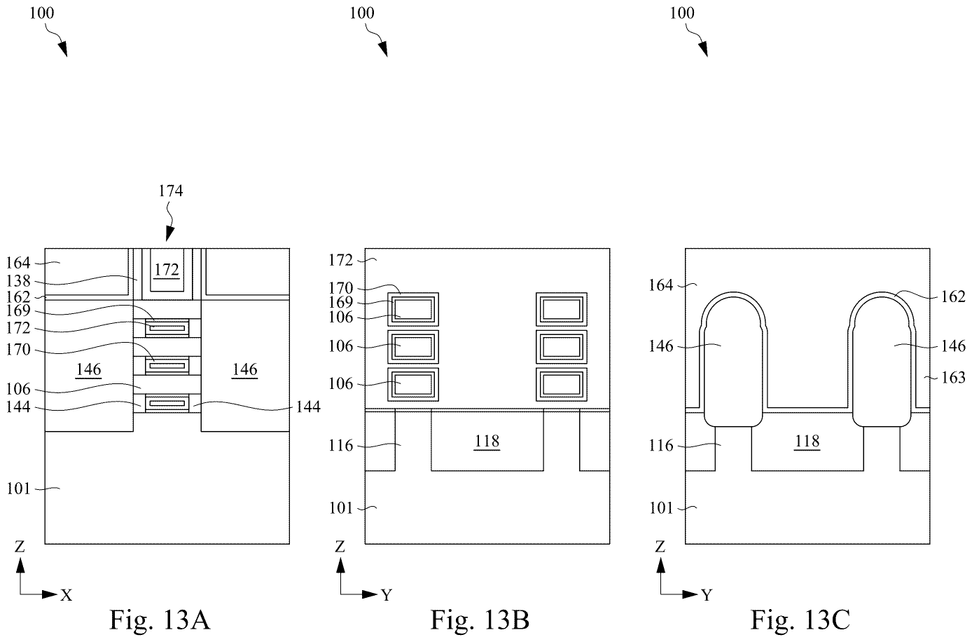

FIGS. 13A, 13B, and 13C are cross-sectional side views of one of various stages of manufacturing the semiconductor device structure 100 taken along line A-A, line B-B, and line C-C of FIG. 6, respectively, in accordance with some embodiments. As shown in FIGS. 13A and 13B, a gate electrode layer 172 is formed on the gate dielectric layer 170. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. In some embodiments, the gate electrode layer 172 includes one or more work function layers and a bulk fill layer. The gate electrode layer 172 may be also deposited over the ILD layer 164. The gate dielectric layer 170 and the gate electrode layer 172 formed over the ILD layer 164 are then removed by using, for example, CMP, until the ILD layer 164 is exposed. The gate dielectric layer 170 and the gate electrode layer 172 may be referred to as a gate structure 174.

As shown in FIGS. 13A, 13B, and 13C, the semiconductor device structure 100 includes at least one transistor, such as a GAA FET, including the gate structure 174, the S/D regions 146 on opposite sides of the gate structure 174, and the first semiconductor layers 106 functioning as channels located between the S/D regions 146. In some embodiments, the transistor may be a FinFET or a planar FET. The transistor may be an NFET or a PFET. In some embodiments, the semiconductor device structure 100 includes a plurality of transistors of a first conductivity type. For example, the plurality of transistors are all NFETs or PFETs.

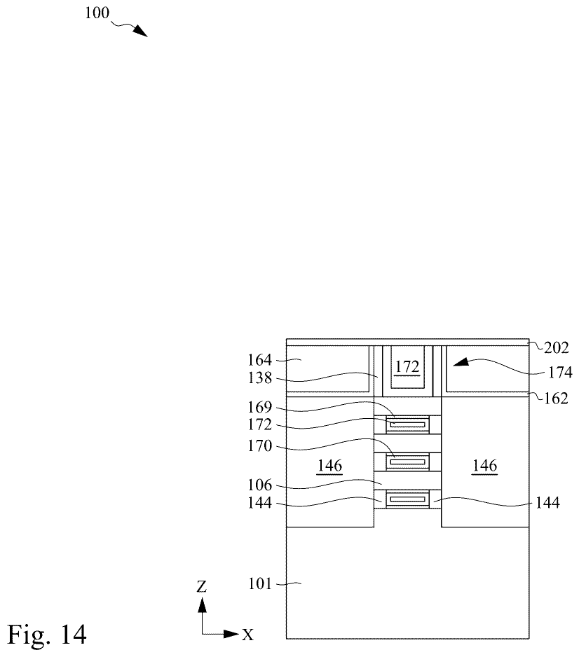

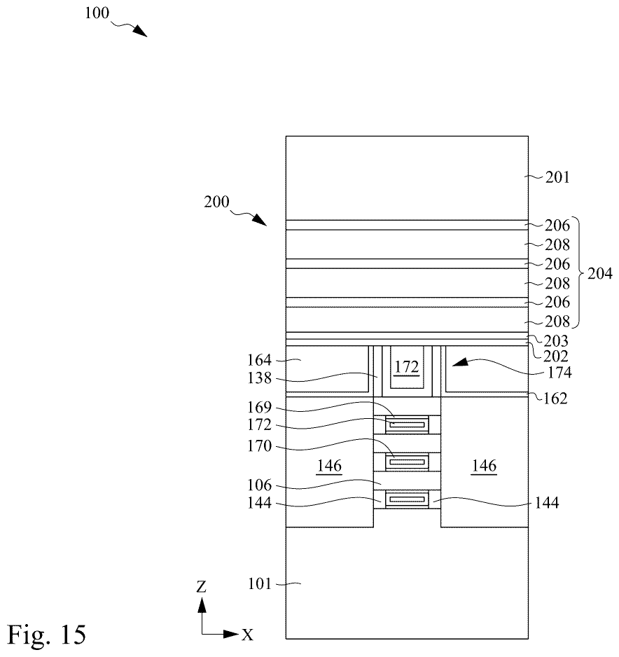

FIGS. 14, 15, 16, 17, 18, 19, 20, 21, and 22 are cross-sectional side views of various stages of manufacturing the semiconductor device structure 100 taken along line A-A of FIG. 6, in accordance with some embodiments. FIGS. 14-22 illustrate a process to form complementary field effect transistors (CFETs), which can provide further density reduction for advanced IC technology nodes. As shown in FIG. 14, a dielectric layer 202 is formed on the ILD layer 164 and the gate structure 174. The dielectric layer 202 may be an oxide layer. Next, as shown in FIG. 15, a structure 200 is bonded to the dielectric layer 202. In some embodiments, the structure 200 includes a dielectric layer 203, a stack of semiconductor layers 204, and a substrate 201. The structure 200 may be formed by forming the stack of semiconductor layers 204 on the substrate 201 and depositing the dielectric layer 203 on the stack of semiconductor layers 204. The structure 200 is then flipped over so the dielectric layer 203 is bonded to the dielectric layer 202. In some embodiments, the dielectric layer 203 is an oxide layer, and the bonding of the dielectric layers 202, 203 is a dielectric-to-dielectric bonding process, such as an oxide-to-oxide bonding process. In some embodiments, the combined thickness of the dielectric layers 202, 203 ranges from about 10 nm to about 100 nm.

The stack of semiconductor layers 204 includes alternating semiconductor layers 206, 208. In some embodiments, the semiconductor layer 206 includes the same material as the first semiconductor layer 106, and the semiconductor layer 208 includes the same material as the second semiconductor layer 208. The substrate 201 may include the same material as the substrate 101. The semiconductor layers 206 or portions thereof may form nanostructure channels of the upper-level transistors of the CFETs in later fabrication stages. Three semiconductor layers 206 and three semiconductor layers 208 are alternately arranged as illustrated in FIG. 15, which is for illustrative purposes and not intended to be limiting beyond what is specifically recited in the claims. It can be appreciated that any number of the semiconductor layers 206, 208 can be formed in the stack of semiconductor layers 104.

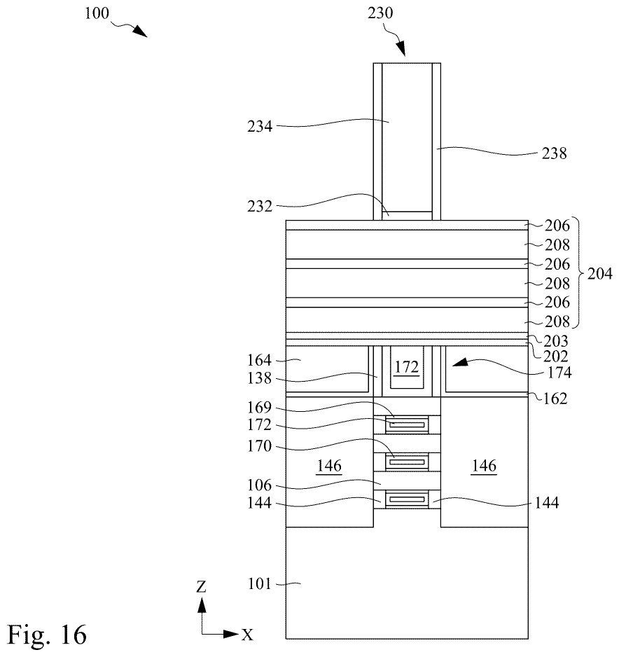

As shown in FIG. 16, the substrate 201 is removed, and one or more sacrificial gate structures 230 (only one is shown) are formed over the stack of semiconductor layers 204. The substrate 201 may be removed by any suitable process. In some embodiments, a thinning process, such as a planarization process, may be performed to remove the substrate 201. An etch stop layer (not shown) may be formed between the topmost semiconductor layer 206 and the substrate 201. The etch stop layer is removed after the removal of the substrate 201. The sacrificial gate structure 230 includes a sacrificial gate dielectric layer 232 and a sacrificial gate electrode layer 234. In some embodiments, the sacrificial gate dielectric layer 232 includes the same material as the sacrificial gate dielectric layer 132, and the sacrificial gate electrode layer 234 includes the same material as the sacrificial gate electrode layer 134. A mask layer (not shown) may be formed on the sacrificial gate electrode layer 234. The mask layer may include the same material as the mask layer 136. The sacrificial gate dielectric layer 232 and the sacrificial gate electrode layer 234 may be formed by the same processes as the sacrificial gate dielectric layer 232 and the sacrificial gate electrode layer 234. After forming the sacrificial gate structure 230, gate spacers 238 are formed on sidewalls of the sacrificial gate structures 230. The gate spacers 238 may include the same material as the gate spacers 138 and may be formed by the same process as the gate spacers 138.

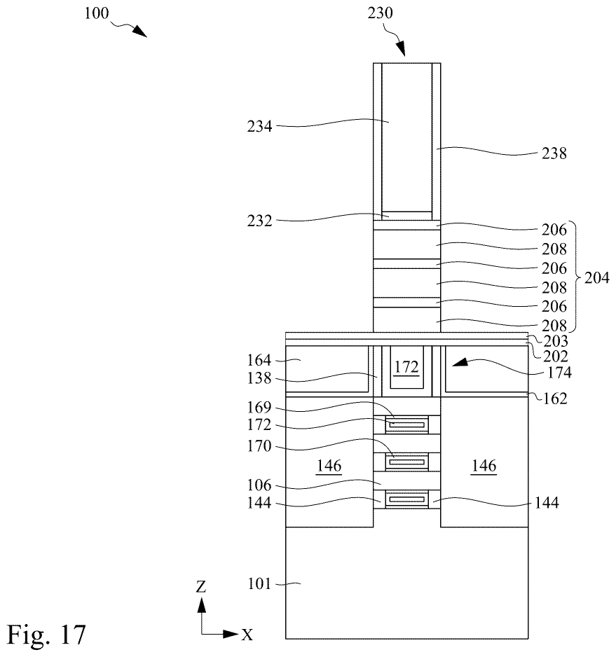

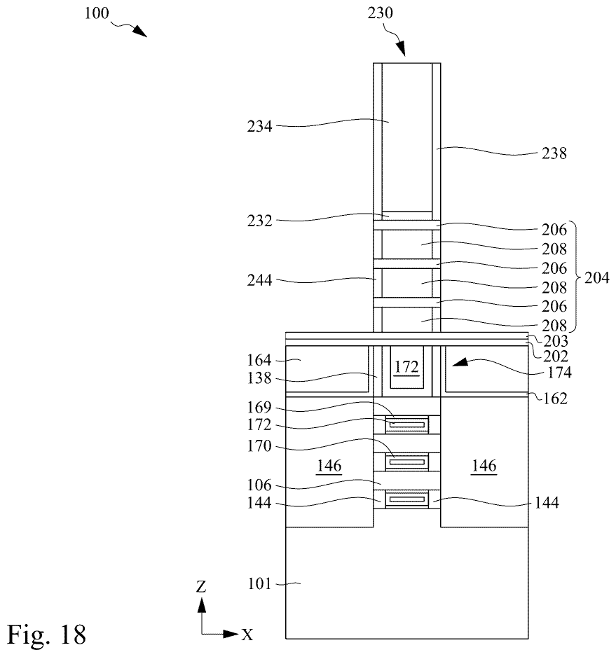

As shown in FIG. 17, the exposed portions of the stack of semiconductor layers 204 are removed. The exposed portions of the stack of semiconductor layers 204 may be removed by the process of recessing the exposed portions of the fin structures 112 described in FIG. 6. Next, edge portions of the semiconductor layers 208 are removed, and dielectric spacers 244 are formed, as shown in FIG. 18. The edge portions of the semiconductor layers 208 may be removed by the process to remove the edge portions of the second semiconductor layers 108 described in FIG. 8A. The dielectric spacers 244 may include the same material as the dielectric spacers 144 and may be formed by the same process as the dielectric spacers 144.

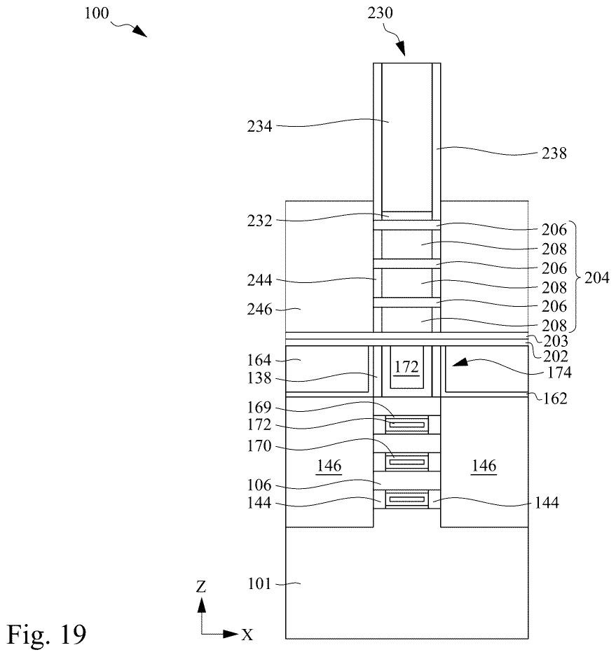

As shown in FIG. 19, S/D regions 246 are formed from the semiconductor layers 206. In some embodiments, the S/D regions 246 may grow both vertically and horizontally to form facets, which may correspond to crystalline planes of the material used for the semiconductor layers 206. The S/D regions 246 may be made of one or more layers of Si, SiP, SiC and SiCP for n-channel FETs or one or more layers of Si, SiGe, Ge for p-channel FETs. For p-channel FETs, p-type dopants, such as boron (B), may also be included in the S/D regions 246. The S/D regions 246 may be formed by an epitaxial growth method using CVD, ALD or MBE. In some embodiments, the S/D regions 146 are a first conductivity type, and the S/D regions 246 are a second conductivity type opposite the first conductivity type. For example, the S/D regions 146 include n-type semiconductor material, and the S/D regions 246 include p-type semiconductor material.

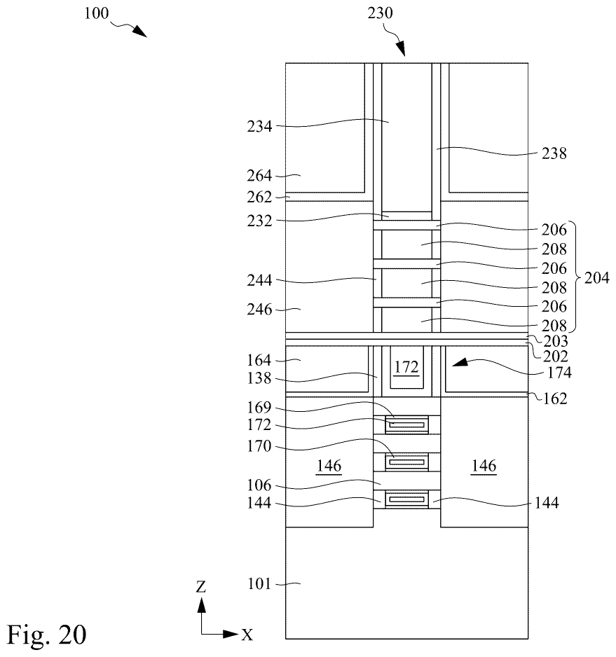

As shown in FIG. 20, CESL 262 and ILD layer 264 are formed over the S/D regions 246. In some embodiments, The CESL 262 includes the same material as the CESL 162 and is formed by the same process as the CESL 262. The ILD layer 264 may include the same material as the ILD layer 164 and may be formed by the same process as the ILD layer 164. A planarization process, such as a CMP process, may be performed to remove portions of the CESL 262 and ILD layer 264 formed over the sacrificial gate electrode layer 234. The mask layer may be also removed by the CMP process to expose the sacrificial gate electrode layer 234.

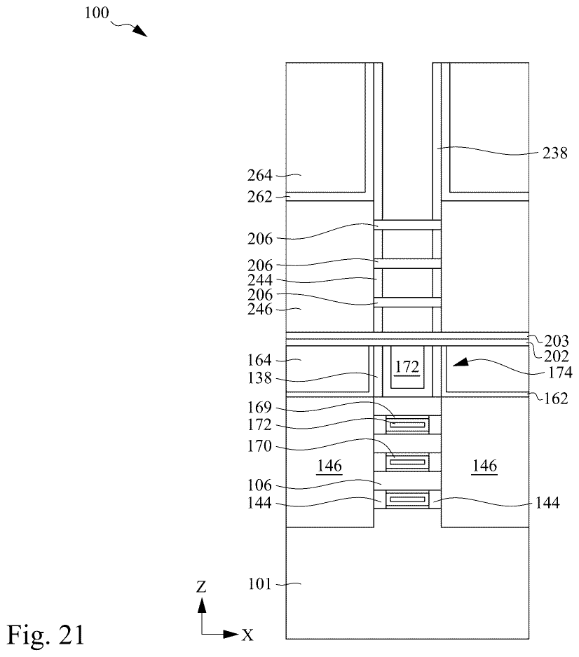

As shown in FIG. 21, the sacrificial gate structures 230 and the semiconductor layers 208 are removed. The sacrificial gate structures 230 may be removed by the same process as the sacrificial gate structures 130, and the semiconductor layers 208 may be removed by the same process as the second semiconductor layers 108. An opening is formed between the gate spacers 238 and between the semiconductor layers 206, as shown in FIG. 21.

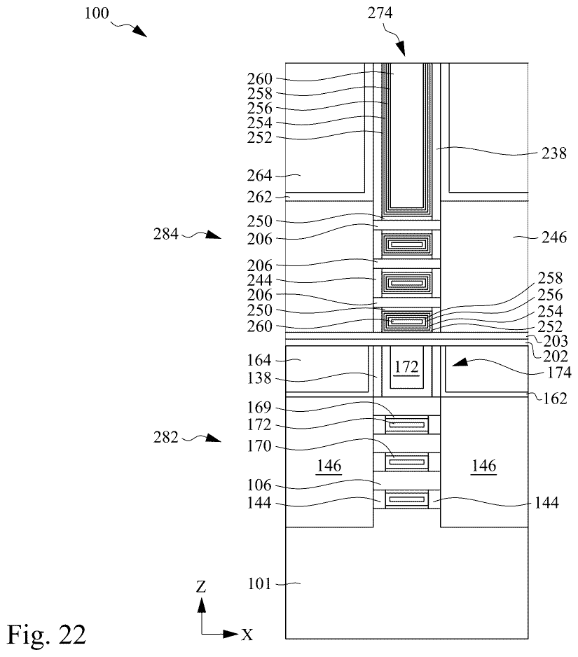

As shown in FIG. 22, a gate structure 274 is formed in the opening between the gate spacers 238 and between the semiconductor layers 206. The processing temperature of the processes to form the gate structure 274 is lower than 400 degrees Celsius, such as from about 20 degrees Celsius to about 350 degrees Celsius. If the processing temperature is greater than about 400 degrees Celsius, materials of the gate electrode layer 172 may be degraded.

In some embodiments, as shown in FIG. 22, an interfacial layer (IL) 250 is formed on exposed surfaces of the semiconductor layers 206. The IL 250 may be an oxide. In some embodiments, the IL 250 is formed by oxidizing the semiconductor layers 206. In some embodiments, the IL 250 has a thickness ranging from about 1 nm to about 1.5 nm. Next, a first gate dielectric layer 252 is deposited on the gate spacers 138 and the IL 250. The first gate dielectric layer 252 may include the same material as the gate dielectric layer 170. In some embodiments, the gate dielectric layer 252 has a thickness ranging from about 3 angstroms to about 5 angstroms. In some embodiments, the gate dielectric layer 252 is just thick enough to form a continuous layer. The gate dielectric layer 252 may be deposited by any suitable process, such as ALD or CVD. In some embodiments, the subsequently formed dipole layer 256 can generate remote electric field during usage, and the gate dielectric layer 252 is formed between the first semiconductor layer 106 and the subsequently formed dipole layer 256 to shield the first semiconductor layer 106 (i.e., the channel region) from the remote electric field generated by the dipole layer 256. In some embodiments, the presence of the gate dielectric layer 252 can lead to Dit reduction. Next, another IL 254 is deposited on the gate dielectric layer 252. In some embodiments, the IL 254 is an oxide, such as silicon oxide. The IL 254 may be deposited by any suitable process, such as ALD or CVD. In some embodiments, the IL 254 has a thickness ranging from about 3 angstroms to about 5 angstroms. In some embodiments, the IL 254 is just thick enough to form a continuous layer. In some embodiments, the thickness of the IL 254 is substantially less than the thickness of the IL 250. For example, a ratio of the thickness of the IL 250 to the thickness of the IL 254 may be between 2 and 3. A dipole layer 256 is then deposited on the IL 254. The dipole layer 256 may be a dielectric layer including n-dipole dopants or p-dipole dopants. In some embodiments, the dipole layer 256 includes a metal, such as La, Sr, Er, Mg, for n-dipole dopant or Al or Ti for p-dipole dopant. The dipole layer 256 may include oxygen, nitrogen, carbon, or combinations thereof. In some embodiments, the dipole layer 256 includes the p-dipole dopant. In some embodiments, the gate dielectric layer 170 includes a dopant of a first conductivity type, and the dipole layer 256 includes a second conductivity type opposite the first conductivity type. In some embodiments, the dipole layer 256 has a thickness ranging from about 3 angstroms to about 5 angstroms. In some embodiments, the dipole layer 256 is just thick enough to form a continuous layer.

The processes to deposit the gate dielectric layer 252, the IL 254, and the dipole layer 256 are performed at low temperatures, such as temperatures below 400 degrees Celsius, for example from about 20 degrees Celsius to about 350 degrees Celsius. At the low temperatures, the n-dipole dopant or the p-dipole dopant does not diffuse into the adjacent layers. Thus, the IL 254 and the gate dielectric layer 252 are substantially free of the n-dipole dopant and the p-dipole dopant. In some embodiments, the peak n-dipole dopant concentration or the peak p-dipole dopant concentration is located within the dipole layer 256. As described above, the peak n-dipole dopant concentration or the peak p-dipole dopant concentration is located at the interface between the gate dielectric layer 170 and the IL 169. Thus, in some embodiments, in a CFET structure, a bottom transistor includes a first conductivity type dipole dopant, and the peak concentration of the first conductivity type dipole dopant is located at an interface between a gate dielectric layer 170 and an IL 169. A top transistor of the CFET structure includes a second conductivity type dipole dopant opposite the first conductivity type, and the peak concentration of the second conductivity type dipole dopant is located within a dipole layer 256. In some embodiments, the first conductivity type is p-type, and the second conductivity type is n-type. In some embodiments, the first conductivity type is n-type, and the second conductivity type is p-type. The gate dielectric layer 252, the IL 254, and the dipole layer 256 can tune the threshold voltage without the need to diffuse the dopant from the dipole layer 256 into the gate dielectric layer 252 or the IL 254. Furthermore, even though the k values of the IL 254 and the dipole layer 256 are smaller than the k value of the gate dielectric layer 252, the thicknesses of the IL 254 and the dipole layer 256 are small, so parasitic capacitance is not substantially increased. In addition, the addition of the IL 254 and the dipole layer 256 creates discontinuous gate structure 274 that prevents the percolation path creation during device operation. In other words, current leakage during operation is reduced. Because the dipole layer 256 and the IL 250 are separated by the gate dielectric layer 252 and the IL 254, the density of interface trap charge (Dit) may be decreased, resulting in reduced leakage current.

In some embodiments, the dipole layer 256 and the IL 254 are capable of bi-directional threshold voltage tunning. For example, if the dipole layer 256 includes n-dipole dopant and is deposited on the IL 254 (or the dipole layer 256 is inside of the IL 254), the threshold voltage may be tuned to be more n-type. If the IL 254 is deposited on the dipole layer 256 (or the IL 254 is inside of the dipole layer 256), the threshold voltage may be tuned to be more p-type. In other words, the dipole layer 256 including a single conductivity type dopant (n-dipole dopant or p-dipole dopant) may be used in both PFETs and NFETs.

Next, a gate dielectric layer 258 is deposited on the dipole layer 256. The gate dielectric layer 258 may include the same material as the gate dielectric layer 170 and may be formed by the same process as the gate dielectric layer 170. The gate dielectric layer 258 is deposited at a low temperature, such as a temperature below 400 degrees Celsius, for example from about 20 degrees Celsius to about 350 degrees Celsius. As described above, at the low temperature, the dopant in the dipole layer 256 does not diffuse into the adjacent layers, such as the IL 254 or the gate dielectric layer 258. Thus, in some embodiments, the gate dielectric layer 258 is substantially free of n-dipole dopant and the p-dipole dopant. In some embodiments, the gate dielectric layer 258 has a thickness ranging from about 0.5 nm to about 1.0 nm. In some embodiments, the gate dielectric layer 258 and the gate dielectric layer 252 include the same material. By inserting the IL 254 and the dipole layer 256 between the gate dielectric layers 252, 258, the threshold voltage can be tuned.

In some embodiments, the IL 250 has a thickness ranging from about 1 nm to about 1.5 nm, the gate dielectric layer 252 has a thickness ranging from about 3 angstroms to about 5 angstroms, the IL 254 has a thickness ranging from about 3 angstroms to about 5 angstroms, the dipole layer 256 has a thickness ranging from about 3 angstroms to about 5 angstroms, and the gate dielectric layer 258 has a thickness ranging from about 0.5 nm to about 1.0 nm. In some embodiments, the total thickness of the IL 250, the gate dielectric layer 252, the IL 254, the dipole layer 256, and the gate dielectric layer 258 ranges from about 2.4 nm to about 4 nm. In some embodiments, the IL 169 and the IL 250 has the same thickness, and the thickness of the gate dielectric layer 170 is the same as the sum of the thicknesses of the gate dielectric layers 252, 258. In some embodiments, the total thickness of the IL 169 and the gate dielectric layer 170 ranges from about 1.8 nm to about 3 nm, which is less than the total thickness of the IL 250, the gate dielectric layer 252, the IL 254, the dipole layer 256, and the gate dielectric layer 258. In other words, in some embodiments, the thickness of the dielectric layers of a gate structure 174 is less than the thickness of the dielectric layers of the gate structure 274.

A gate electrode layer 260 is formed on the gate dielectric layer 258. The gate electrode layer 260 may include the same materials as the gate electrode layer 172. In some embodiments, the gate electrode layer 260 includes one or more work function layers, and each work function layer includes Ti, Al, Ag, Mn, Zr, TiC, TiAl, TiAlC, TiAlSiC, TaC, TaCN, TaSiN, TiSiN, TiN, TaN, Ru, Mo, WN, WCN, ZrSi₂, MoSi₂, TaSi₂, NiSi₂, TaAl, TaAlC, TaSiAlC, or TiAlN. The gate electrode layer 260 further includes a bulk fill layer made of an electrically conductive material, such as Al, W, Cu, Ti, Ta, TiN, TaN, polysilicon, other suitable metal(s) and/or alloys thereof, or a combination thereof.

In some embodiments, the semiconductor device structure 100 includes a CFET having a first transistor 282 and a second transistor 284 disposed over the first transistor 282. The first transistor 282 includes a first gate structure 174 having a first number of layers, and the second transistor 284 includes a second gate structure 274 having a second number of layers greater than the first number. For example, the second gate structure 274 includes three more layers than the first gate structure 174, and the three layers are the gate dielectric layer 252, the IL 254, and the dipole layer 256. The first gate structure 174 may include a gate dielectric layer 170 having n-dipole dopant or p-dipole dopant, and the second gate structure 174 may include gate dielectric layers 252, 258 that are free of the n-dipole dopant and the p-dipole dopant. The second gate structure 174 is formed at a low temperature less than about 400 degrees Celsius, such as from about 20 degrees Celsius to about 350 degrees Celsius. As a result, the metal layers of the first gate structure 174 are not degraded.

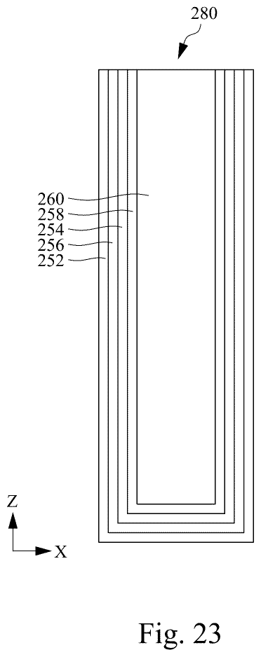

FIG. 23 is a cross-sectional side view of a portion of a gate structure 280, in accordance with alternative embodiments. As shown in FIG. 23, the gate structure 280 includes the gate dielectric layer 252, the dipole layer 256 disposed on the gate dielectric layer 252, the IL 254 disposed on the dipole layer 256, the gate dielectric layer 258 disposed on the IL 254, and the gate electrode layer 260 disposed on the gate dielectric layer 258. The portion of the gate electrode structure 280 shown in FIG. 23 is the portion located between the gate spacers 138, and the gate structure 280 also include portions (not shown) located between vertical first semiconductor layers 106 (or the vertical semiconductor layers 206) (FIG. 22). In some embodiments, in the CFET described above, the first transistor 282 is a FET of a first conductivity type and includes the gate structure 280. The second transistor 284 is a FET of a second conductivity type opposite the first conductivity type and includes the gate structure 274. In such embodiments, the dipole layers 256 of the gate structure 280 and the dipole layer 256 of the gate structure 274 include the same material. Because the relative locations of the IL 254 and the dipole layer 256 are different in the gate structures 274, 280, the conductivity types are different for the first and second transistors 282, 284. In some embodiments, the first transistor 282 and the second transistor 284 are located on the same level. For example, the first transistor 282 is located in a PMOS region and the second transistor 284 is located in an NMOS region adjacent the PMOS region along the X or Y direction. The first transistor includes the gate structure 280, and the second transistor includes the gate structure 274. The dipole layers 256 of the gate structures 280, 274 include the same material.

Embodiments of the present disclosure provide a semiconductor device structure and methods of forming the same. In some embodiments, the semiconductor device structure includes a first gate structure 174 and a second gate structure 274 disposed over the first gate structure 174. The first and second gate structures 174, 274 are formed using different processes and include different number of layers. The second gate structure 274 are formed by processes having a low processing temperature. Some embodiments may achieve advantages. For example, with the low processing temperature, the materials of the first gate structure 174 are not degraded because the second gate structure 274 is formed after the formation of the first gate structure 174.

An embodiment is a CFET structure. The structure includes a first transistor including a first gate structure including a first number of dielectric layers and a first conductivity type dipole dopant, and a peak concentration of the first conductivity type dipole dopant is located at an interface between a first interfacial layer and a first gate dielectric layer of the first number of dielectric layers. The structure further includes a second transistor disposed over the first transistor, and the second transistor includes a second gate structure including a second number of dielectric layers and a second conductivity type dipole dopant opposite the first conductivity type, the second number is different from the first number, and a peak concentration of the second conductivity type dipole dopant is located in a dipole layer of the second number of dielectric layers.

Another embodiment is a semiconductor device structure. The structure includes a semiconductor layer, a first source/drain region disposed on a first side of the semiconductor layer, a second source/drain region disposed on a second side of the semiconductor layer opposite the first side, and a first gate structure disposed over the semiconductor layer. The first gate structure includes a first interfacial layer and a dipole layer adjacent the first interfacial layer. The dipole layer has a thickness ranging from about 3 angstroms to about 5 angstroms.

A further embodiment is a method for forming a semiconductor device structure. The method includes forming a first gate structure over a semiconductor layer. The method for forming the first gate structure includes depositing a first gate dielectric layer, depositing a first dipole layer on the first gate dielectric layer, and performing a thermal process to diffuse a dopant from the first dipole layer into the first gate dielectric layer. The thermal process has a first processing temperature. The method for forming the first gate structure further includes removing the first dipole layer. The method further includes forming a second gate structure over the first gate structure. The method for forming the second gate structure includes depositing a first interfacial layer, depositing a second dipole layer, and depositing a second gate dielectric layer on the second dipole layer. Processes of the depositing of the first interfacial layer, the depositing of the second dipole layer, and the depositing of the second gate dielectric layer have second processing temperatures lower than the first processing temperature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A complementary field effect transistor (CFET) structure, comprising:
a first transistor comprising a first gate structure including a first number of dielectric layers and a first conductivity type dipole dopant, wherein a peak concentration of the first conductivity type dipole dopant is located at an interface between a first interfacial layer and a first gate dielectric layer of the first number of dielectric layers; and
a second transistor disposed over the first transistor, wherein the second transistor comprises a second gate structure including a second number of dielectric layers and a second conductivity type dipole dopant opposite the first conductivity type, the second number is different from the first number, and a peak concentration of the second conductivity type dipole dopant is located in a dipole layer of the second number of dielectric layers.

2. The CFET structure of claim 1, wherein the first gate structure comprises the first interfacial layer, the first gate dielectric layer, and a first gate electrode layer.

3. The CFET structure of claim 2, wherein the second gate structure comprises a second interfacial layer, a second gate dielectric layer, a third interfacial layer, the dipole layer, a third gate dielectric layer, and a second gate electrode layer.

4. The CFET structure of claim 3, wherein the second and third gate dielectric layers are substantially free of the second conductivity type dipole dopant.

5. The CFET structure of claim 3, wherein the first interfacial layer and the second interfacial layer have a same thickness, which is greater than a thickness of the third interfacial layer.

6. The CFET structure of claim 5, wherein a total thickness of the second and third gate dielectric layers is the same as a thickness of the first gate dielectric layer.

7. The CFET structure of claim 3, wherein the second and third interfacial layers are formed by different processes.

8. A semiconductor device structure, comprising:
a semiconductor layer;
a first source/drain region disposed on a first side of the semiconductor layer;
a second source/drain region disposed on a second side of the semiconductor layer opposite the first side;
a first gate structure disposed over the semiconductor layer, wherein the first gate structure comprises:
a first interfacial layer; and
a dipole layer adjacent the first interfacial layer, wherein the dipole layer has a thickness ranging from about 3 angstroms to about 5 angstroms.

9. The semiconductor device structure of claim 8, wherein the first gate structure further comprises a second interfacial layer, a first gate dielectric layer, a second gate dielectric layer, and a gate electrode layer.

10. The semiconductor device structure of claim 8, wherein the first interfacial layer and the second interfacial layer are formed by different processes.

11. The semiconductor device structure of claim 9, further comprising a second gate structure disposed below the first gate structure.

12. The semiconductor device structure of claim 11, wherein the second gate structure comprises a third interfacial layer and a third gate dielectric layer.

13. The semiconductor device structure of claim 12, wherein the first interfacial layer and the third interfacial layer have a same thickness.

14. The semiconductor device structure of claim 13, wherein the second gate dielectric layer has a thickness less than a thickness of the third gate dielectric layer.

15. The semiconductor device structure of claim 14, wherein a total thickness of the first and second gate dielectric layer is the same as the thickness of the third gate dielectric layer.

16. The semiconductor device structure of claim 8, wherein the dipole layer comprises a metal and oxygen, nitrogen, carbon, or combinations thereof.

17. A method for forming a semiconductor device structure, comprising:
forming a first gate structure over a semiconductor layer, comprising:
depositing a first gate dielectric layer;
depositing a first dipole layer on the first gate dielectric layer;
performing a thermal process to diffuse a dopant from the first dipole layer into the first gate dielectric layer, wherein the thermal process has a first processing temperature; and
removing the first dipole layer; and
forming a second gate structure over the first gate structure, comprising:
depositing a first interfacial layer;
depositing a second dipole layer; and
depositing a second gate dielectric layer on the second dipole layer, wherein processes of the depositing of the first interfacial layer, the depositing of the second dipole layer, and the depositing of the second gate dielectric layer have second processing temperatures lower than the first processing temperature.

18. The method of claim 17, wherein the forming of the first gate structure further comprises forming a second interfacial layer by a first process different from a second process of depositing the first interfacial layer.

19. The method of claim 18, wherein the forming of the second gate structure further comprises forming a third interfacial layer by the first process.

20. The method of claim 19, wherein the first process is an oxidation process, and the second process is an atomic layer deposition process or a chemical vapor deposition process.
